(19) United States
(12) Patent Application Publication
(10) Pub. No.: US 2009/0026562 A1
(43) Pub. Date: Jan. 29, 2009

(54) Package structure for optoelectronic device

(75) Inventors: Kai-Chih Wang, Taoyuan (TW); Fang-Chang Liu, Hsinchu (TW); I-Pang Chou, Taoyuan (TW)

Correspondence Address: BIRCH STEWART KOLASCH & BIRCH, PO BOX 747, FALLS CHURCH, VA, 22040-0747, US

(73) Assignee: VisEra Technologies Company Limited

(21) Appl. No.: 11/878,762

(22) Filed: Jul. 26, 2007

(51) Int. Cl. H01L 31/00

(52) U.S. Cl. 257/432; 257/E31.001

(57) ABSTRACT

A package structure for an optoelectronic device. The package structure comprises a device chip interposed between a lower transparent substrate and an upper transparent substrate. The device chip comprises a semiconductor substrate comprising a device region surrounded by a pad region, in which the pad region comprises a plurality of notches along the edges of the semiconductor substrate. A dielectric layer is between the semiconductor substrate and the upper transparent substrate, comprising a plurality of pads formed therein and substantially aligned with the plurality of notches, respectively. A plurality of metal lines is disposed under a bottom surface of the lower transparent substrate. A plurality of solder balls disposed under the plurality of metal lines, respectively.

### BACKGROUND OF THE INVENTION

1. Field of the Invention

The invention relates to semiconductor package technology and in particular to a wafer-level chip scale package (WLCSP) structure for an optoelectronic device.

2. Description of the Related Art

Digital image devices are widely used in digital cameras, digital video recorders, cellular phones with image capture function, and monitors. A digital imaging sensor typically includes an optoelectronic device chip, such as a charge-coupled device (CCD) image sensor chip or CMOS image sensor chip. The digital imaging sensor is capable of converting a portion of an optical image into an electronic signal. The electronic signal is then used to regenerate the optical image on, for example, a display.

Such image sensor chips may be further packaged by an advanced package technology called “WLCSP”. In traditional package technology, a wafer with micro-devices, such as electronic devices, electromechanical devices or optoelectronic devices formed thereon, is first diced into multiple chips, and thereafter the chips are packaged. Unlike traditional package technology, WLCSP technology micro-devices may be packaged prior to dicing a wafer into multiple chips. WLCSP for image sensor chips is manufacturable because the active area of the image sensor is on one side of the image sensor chip bonded to a glass substrate and the ball grid array for the interconnection is placed on the other side of the chip.

### BRIEF SUMMARY OF THE INVENTION

A detailed description is given in the following embodiments with reference to the accompanying drawings. A package structure for an optoelectronic device is provided. An embodiment of a package structure for an optoelectronic device comprises a device chip interposed between a lower transparent substrate and an upper transparent substrate. The device chip comprises a semiconductor substrate comprising a device region surrounded by a pad region, in which the pad region comprises a plurality of notches along the edges of the semiconductor substrate. A dielectric layer is between the semiconductor substrate and the upper transparent substrate, comprising a plurality of pads formed therein and substantially aligned with the plurality of notches, respectively. A plurality of metal lines is disposed under a bottom surface of the lower transparent substrate. A plurality of solder balls is disposed under the plurality of metal lines, respectively.

### BRIEF DESCRIPTION OF DRAWINGS

The invention can be more fully understood by reading the subsequent detailed description and examples with references made to the accompanying drawings, wherein:

FIG. 1 is a simplified plan view of a semiconductor wafer that including a plurality of optoelectronic devices;

FIG. 2A is a partial simplified plan view of an embodiment of a package structure for an optoelectronic device after dicing the wafer shown in FIG. 1;

FIG. 2B is a partial plan view of a semiconductor substrate of the package structure shown in FIG. 2A;

FIG. 3A is a cross section along 3A-3A′ line shown in FIG. 2A;

FIG. 3B is a cross section along 3B-3B′ line shown in FIG. 2A;

FIG. 4A is a partial simplified plan view of an embodiment of a package structure for an optoelectronic device after dicing the wafer shown in FIG. 1;

FIG. 4B is a partial plan view of a semiconductor substrate of the package structure shown in FIG. 4A;

FIG. 5A is a cross section along 5A-5A′ line shown in FIG. 4A; and

FIG. 5B is a cross section along 5B-5B′ line shown in FIG. 4A.

### DETAILED DESCRIPTION OF INVENTION

The following description is of the best-contemplated mode of carrying out the invention. This description is provided for the purpose of illustrating the general principles of the invention and should not be taken in a limiting sense. The scope of the invention is best determined by reference to the appended claims.

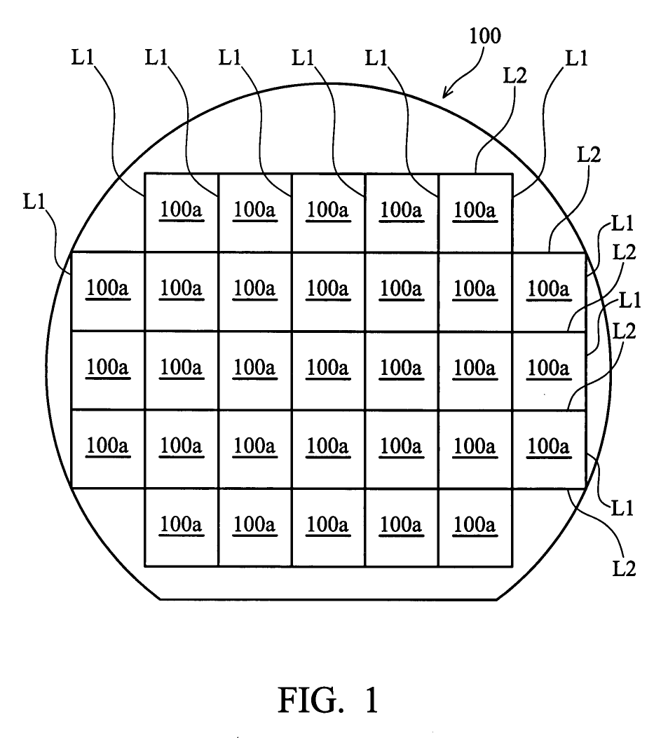

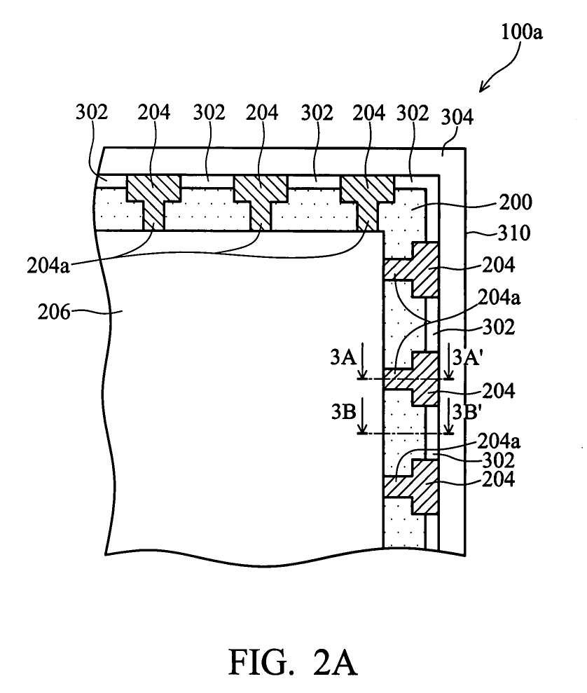

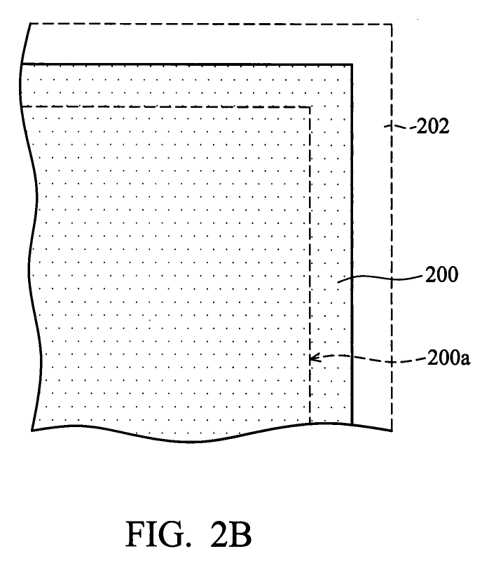

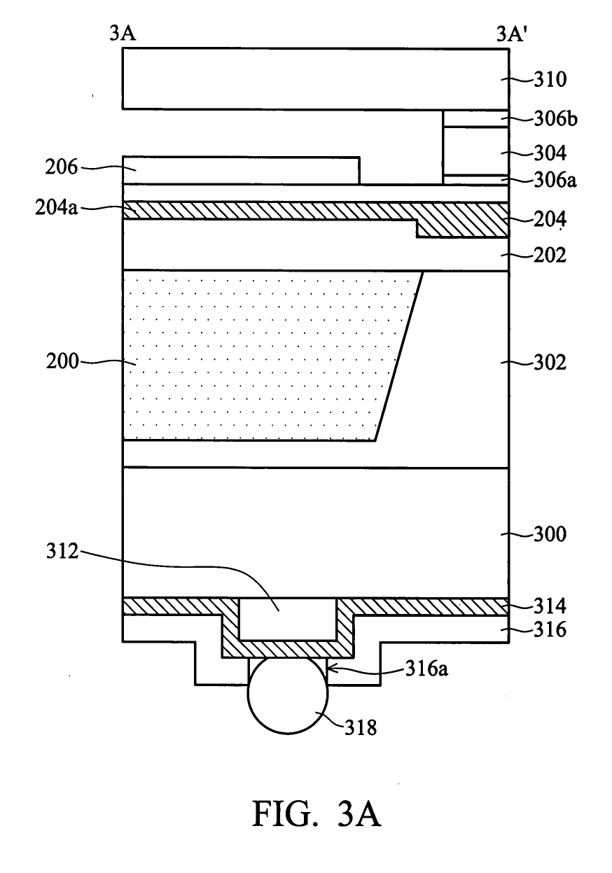

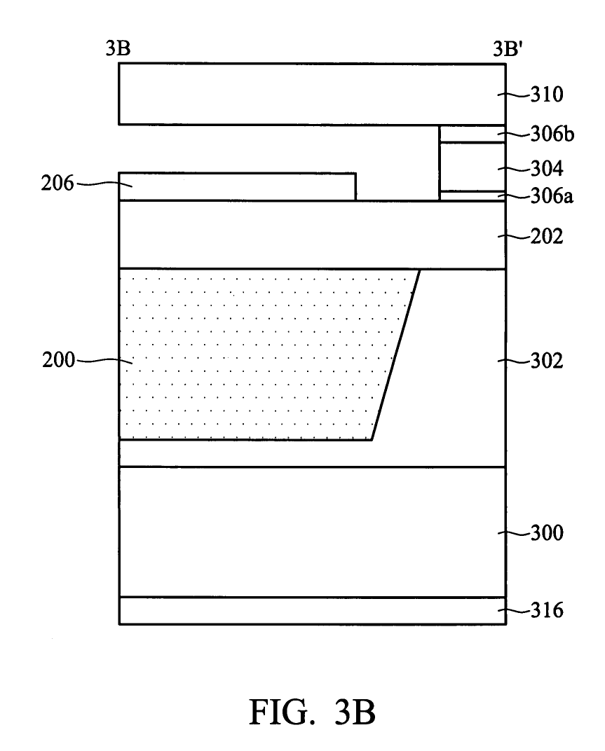

The invention relates to a package structure for an optoelectronic device. FIG. 1 is a simplified plan view of a semiconductor wafer 100 that include a plurality of optoelectronic devices. In the embodiment, the wafer 100 is packaged by WLCSP technology. Accordingly, after the fabrication process is completed and the wafer 100 is diced along a plurality of dicing lanes L1 and L2 to form a plurality of optoelectronic device chips 100a, each optoelectronic device chip 100a is fully packaged. FIG. 2A illustrates a partial simplified plan view of an embodiment of a package structure for the optoelectronic after dicing the wafer 100 shown in FIG. 1. Moreover, FIGS. 3A and 3B are FIG. 2 cross sections, 3A-3A′ and 3B-3B′, respectively.

Referring to FIG. 3A, the packaged structure comprises a lower transparent substrate 300, an upper transparent substrate 310 and an optoelectronic device chip 100a (as shown in FIG. 2A) interposed between the lower transparent substrate 300 and upper transparent substrate 310. The lower and upper transparent substrate 300 and 310, respectively, may comprise glass, quartz or other transparent materials.

Referring to FIG. 2B, the optoelectronic device chip 100a (as shown in FIG. 2A) comprises a semiconductor substrate 200 and a dielectric layer 202 formed on the front surface of the semiconductor substrate 200. Here, the “front surface” indicates an active surface. In the embodiment, the semiconductor substrate 200 comprises silicon substrate or other semiconductor materials. The semiconductor substrate 200 has a device region 200a and may contain a variety of elements in the device regions 200a, including, transistors, resistors, and other semiconductor elements as known in the art. The semiconductor substrate 200 may also contain conductive layers, insulating layers or isolation structures. The conductive layers typically comprises metal, such as copper, commonly used in the semiconductor industry for wiring discrete devices in and on the semiconductor substrate 200. In order to simplify the diagram, a flat semiconductor substrate is depicted.

Referring to FIG. 3A, the dielectric layer 202 on the semiconductor substrate 200 may comprise silicon oxide or other low k materials, such as fluorinated silicate glass (FSG), carbon doped oxide, methyl silsesquioxane (MSQ), hydrogen silsesquioxane (HSQ), or fluorine tetra-ethyl-orthosilicate (FTEOS). Additionally, in some embodiments, the dielectric layer 202 may comprise multiple dielectric layers. A plurality of pads 204 is embedded in the dielectric layer 202. In the embodiment, each pad 204 comprises metal, such as copper or aluminum. Moreover, each pad 204 may further comprise an extended portion 204a electrically connected to the devices (not shown) in and on the semiconductor substrate 200. Typically, the pad 204 laterally contacts a portion of the metal line 314 formed over the sidewall of the semiconductor substrate 200. Should the semiconductor substrate 200 contact the metal line 314 directly, a short circuit will occur. In order to avoid short circuit due to the semiconductor substrate 200 directly contacting the metal line 314, the semiconductor substrate 200 must be inwardly recessed from the edge of the dielectric layer 202, as shown in FIG. 2B.

Referring to FIG. 3A, the semiconductor substrate 200 is bonded with the lower transparent substrate 300 through an adhesive material 302. Moreover, the adhesive material 312 fills the space created by the dielectric layer 202, the inwardly recessed semiconductor substrate 200 and the lower transparent substrate 300. The adhesive material 302 filled in such a space serves as an insulator between the semiconductor substrate 200 and the portion of the metal line 314 formed over the sidewall of the semiconductor substrate 200 to prevent short circuit of device.

A dam 304 is disposed between the dielectric layer 202 and the upper transparent substrate 310 to form a cavity therebetween, such that an optoelectronic device 206, such as a CCD or CMOS image sensor array, can be disposed on the dielectric layer 202 corresponding to the device region 200a and within the cavity. The dam 304 is bonded with the dielectric layer 202 and the upper transparent substrate 310 through adhesive layers 306a and 306b, respectively.

Still referring to FIG. 3A, a plurality of buffer layers 312 is disposed on the bottom surface of the lower transparent substrate 300 and correspondingly covered by a plurality of metal lines 314. A protective layer 316, such as a silicon nitride layer, covers the plurality of metal lines 314 and the bottom surface of the lower transparent substrate 300. The protective layer 316 has a plurality of openings 316a corresponding to the plurality of buffer layers 312 to expose the corresponding metal lines 314. Moreover, a plurality of solder balls 318 is correspondingly disposed in the plurality of openings 316a to electrically connect the corresponding metal lines 314. The solder ball 318 is correspondingly disposed in the opening 316a of the protective layer 316.

Referring to FIG. 2A, in the embodiment, the pad 204 is protruded from the edge of the semiconductor substrate 200 such that the pad 204 is substantially held by the adhesive material 302, rather than the semiconductor substrate 200. Typically, the adhesive material 302 comprises insulating glue with low mechanical strength. Accordingly, when dicing the wafer 100, stress and vibration may be induced, resulting in delamination of the pad 204. Thus, reducing device reliability.

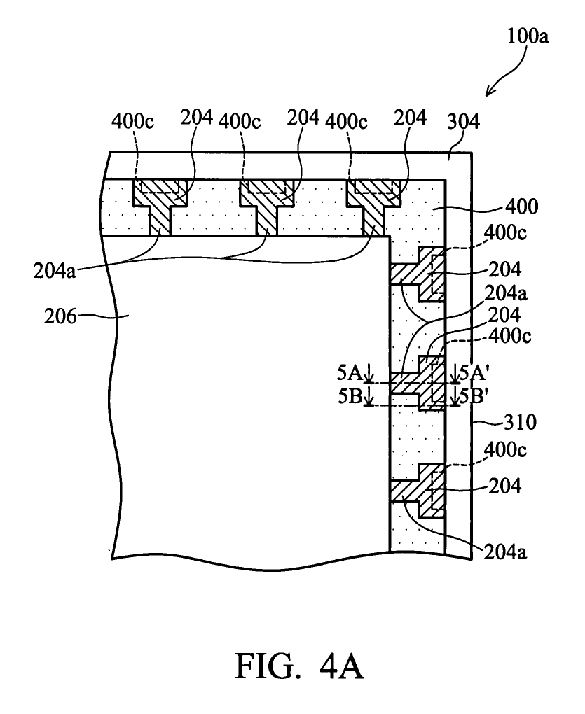

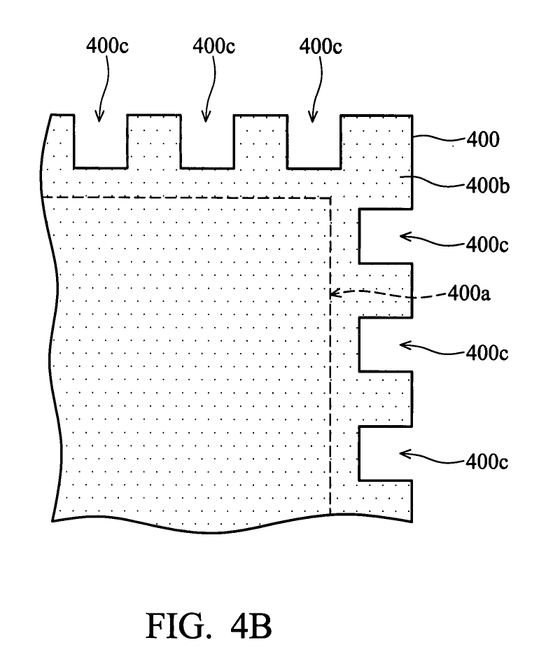

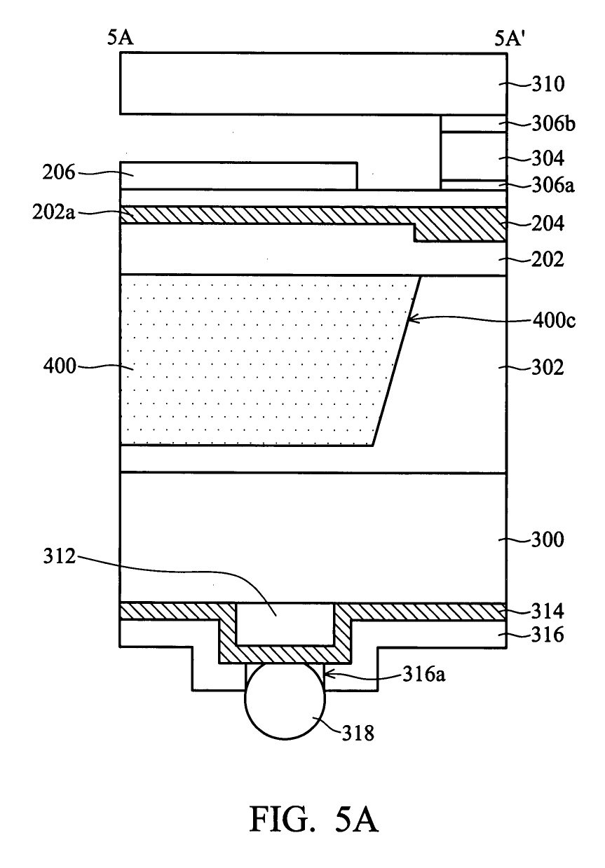

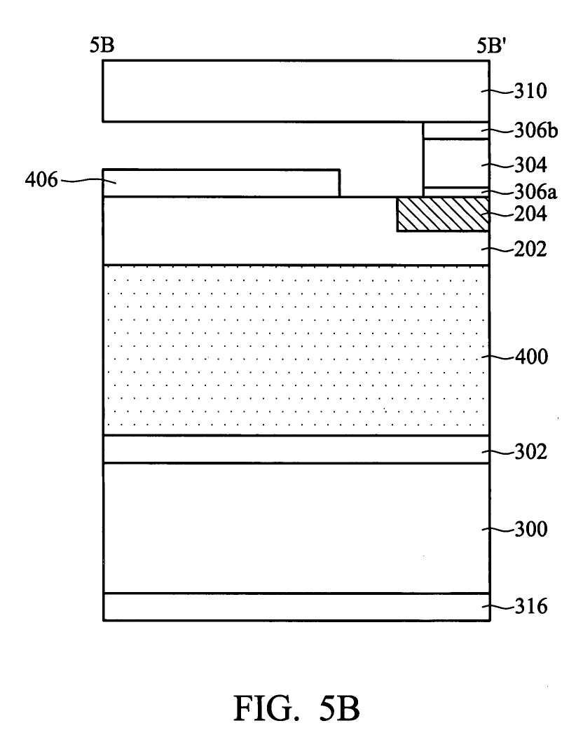

In order to eliminate the problem mentioned above, another embodiment of a package structure for an optoelectronic device is provided. FIG. 4A illustrates a partial simplified plan view of an embodiment of a package structure for the optoelectronic device after dicing the wafer 100 shown in FIG. 1. Moreover, FIGS. 5A and 5B are FIG. 4A cross sections 5A-5A′ and 5B-5B′, respectively. Elements in FIGS. 4A, 5A and 5B that are the same as those in FIGS. 2A, 3A and 3B, respectively, are labeled with the same reference numbers as in FIGS. 2A, 3A and 3B, respectively, and are not described again for brevity. In this embodiment, referring to FIG. 4B, the semiconductor substrate 400 comprise a device region 400a surrounded by a pad region 400b. In particular, the pad region 400b comprises a plurality of notches 400c along the edges of the semiconductor substrate 400. Referring to FIG. 5A, the plurality of pads 204 formed in the dielectric layer 202 is substantially aligned with the plurality of notches 400c, respectively. The adhesive material 302 fills the plurality of notches 400c after bonding the semiconductor substrate 400 with the lower transparent substrate 300 to serve as an insulator between the semiconductor substrate 400 and the portion of the metal line 314 formed over the sidewall of the semiconductor substrate 400 preventing short circuit of device. That is, metal line 314 formed over the sidewall of the semiconductor substrate 400 must have a width narrower than that of the notch 400c. However, in this embodiment, each pad 204 has a width substantially wider than that of each notch 400c, such that the pad 204 can be held not mainly by the adhesive material 302, but also by the semiconductor substrate 400. Therefore, the delamination of the pad 204 during dicing the wafer 100 can be eliminated or mitigated because the portions of the semiconductor substrate 400 on both sides of each notch 400c can provide a better holding than the adhesive material 302 with lower mechanical strength.

According to the this embodiment, since the pad 204 can be simultaneously held by the adhesive material 302 and the semiconductor substrate 400 on both sides of each notch 400c, the delamination of the pad 204 can be eliminated or mitigated, thereby increasing device reliability. Moreover, the adhesive material 302 filled in the notch 400c can serve as an insulator between the metal line 314 and the semiconductor substrate 400, thus preventing short circuit of device.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A package structure for an optoelectronic device, comprising:
a lower transparent substrate and an upper transparent substrate;
a device chip interposed between the lower and upper transparent substrates, comprising:
a dielectric layer between the semiconductor substrate and the upper transparent substrate, comprising a plurality of pads formed therein and substantially aligned with the plurality of notches; and
a semiconductor substrate comprising a device region surrounded by a pad region, wherein the pad region comprises a plurality of notches along the edges of the semiconductor substrate, respectively;
a plurality of metal lines disposed under a bottom surface of the lower transparent substrate; and
a plurality of solder balls disposed under the plurality of metal lines, respectively.

2. The package structure as claimed in claim 1, further comprising a dam disposed between the upper substrate and the dielectric layer to form a cavity therebetween.

3. The package structure as claimed in claim 2, further comprising an optoelectronic device disposed on the dielectric layer in the cavity and correspondingly to the device region.

4. The package structure as claimed in claim 3, wherein the optoelectronic device comprises a CCD or CMOS image sensor array.

5. The package structure as claimed in claim 1, further comprising a protective layer covering the plurality of metal lines except the regions having the plurality of solder balls thereunder.

6. The package structure as claimed in claim 1, wherein each pad has a width substantially wider than that of each notch.

7. The package structure as claimed in claim 1, further comprising an adhesive material formed between the lower transparent substrate and the semiconductor substrate and filling the plurality of notches.

8. The package structure as claimed in claim 1, wherein the lower and upper transparent substrates comprise glass.

9. The package structure as claimed in claim 1, wherein the semiconductor substrate comprises silicon.

10. The package structure as claimed in claim 1, wherein each pad further comprises an extending portion corresponding to the device region.
